(19) United States
(12) Patent Application Publication
(10) Pub. No.: US 2025/0116693 A1
(43) Pub. Date: Apr. 10, 2025

(54) ELECTRICAL GRID ORIGINATION DETERMINATION BY POWER LINE DISTURBANCE CHARACTERISTICS

(71) Applicant: INTERNATIONAL BUSINESS MACHINES CORPORATION, ARMONK, NY (US)

(72) Inventors: Brian Charles Tucker, Clinton Corners, NY (US); Marc Henri Coq, Hopewell Junction, NY (US); Enver Candan, Fishkill, NY (US); Steven G. Shevach, Hurley, NY (US)

(21) Appl. No.: 18/481,366

(22) Filed: Oct. 5, 2023

(51) Int. Cl. G01R 31/08; H02J 13/00

(52) U.S. Cl. CPC G01R 31/086; G01R 31/085; G01R 31/088; H02J 13/00002

(57) ABSTRACT

Described are techniques for electrical grid origination determination using Power Line Disturbance (PLD) characteristics. The techniques include detecting a first PLD in a first voltage feed of a first power unit at a first time. The techniques further include comparing the first PLD to other PLDs aggregated from multiple power units. The techniques further include determining that the first voltage feed of the first power unit originates from a same source as a second power unit based on a similarity between the first PLD and a second PLD of the second power unit satisfying a similarity threshold and occurring within a same timeframe proximate to the first time. The techniques further include recording that the first power unit and the second power unit receive power from a same source.

### BACKGROUND

The present disclosure relates to electronics, and, more specifically, to power management for electronics.

Electronic equipment, such as equipment used in Information Technology (IT), communications, automation, control, industrial, and/or other applications that operates in a high-availability fashion requires a robust electrical power source. Equipment that is designed for such operating conditions generally has separate, redundant, power supplies or connections as part of the equipment.

### SUMMARY

In some aspects, the techniques described herein relate to a computer-implemented method including detecting a first Power Line Disturbance (PLD) in a first voltage feed of a first power unit at a first time. The computer-implemented method further includes comparing the first PLD to other PLDs aggregated from multiple power units. The computer-implemented method further includes determining that the first voltage feed of the first power unit originates from a same source as a second power unit based on a similarity between the first PLD and a second PLD of the second power unit satisfying a similarity threshold and occurring within a same timeframe proximate to the first time. The computer-implemented method further includes recording that the first power unit and the second power unit receive power from a same source.

Additional aspects of the present disclosure are directed to systems and computer program products configured to perform the method described above. The present summary is not intended to illustrate each aspect of, every implementation of, and/or every embodiment of the present disclosure.

### BRIEF DESCRIPTION OF THE DRAWINGS

The drawings included in the present application are incorporated into and form part of the specification. They illustrate embodiments of the present disclosure and, along with the description, serve to explain the principles of the disclosure. The drawings are only illustrative of certain embodiments and do not limit the disclosure.

FIG. 1 illustrates a block diagram of an example system for electrical grid origination determination using Power Line Disturbance (PLD) characteristics, in accordance with some embodiments of the present disclosure.

FIG. 2 illustrates a flowchart of an example method for detecting PLD events at a Power Distribution Unit (PDU), in accordance with some embodiments of the present disclosure.

FIG. 3 illustrates a flowchart of an example method for determining whether detected PLD events indicate two or more PDUs are improperly connected to a same power source, in accordance with some embodiments of the present disclosure.

FIG. 4 illustrates a flowchart of an example method for detecting a misconnection of multiple PDUs to a same power source based on PLD events, in accordance with some embodiments of the present disclosure.

FIG. 5 illustrates a flowchart of an example method for detecting a PLD event, in accordance with some embodiments of the present disclosure.

FIG. 6A illustrates an example table including example similarity thresholds for identifying multiple PLD events as being a same PLD event such as timestamp variation, voltage magnitude deviation, and event duration, in accordance with some embodiments of the present disclosure.

FIG. 6B illustrates an example table including example PLDs and their utility in characterizing electrical grid origination for various PDUs, in accordance with some embodiments of the present disclosure.

FIG. 7 illustrates a block diagram of an example computing environment, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the particular embodiments described. On the contrary, the intention is to cover all modifications, equivalents, and alternatives falling within the spirit and scope of the present disclosure.

### DETAILED DESCRIPTION

Aspects of the present disclosure are directed toward electronics, and, more specifically, to power management for electronics. While not limited to such applications, embodiments of the present disclosure may be better understood in light of the aforementioned context.

Facilities that utilize critical electronic equipment can provide electrical power that is sourced from two separate, independent, utility grids as a mechanism of improving the overall availability of the critical electronic equipment. Within these facilities, there exists the risk that the equipment may not be connected properly (due to human error or other factors) resulting in a condition where the redundant power connections may be connected to the same power feed rather than the intended, redundant power feeds.

A system that is inadvertently misconnected to a non-redundant energy source reduces the overall availability of the connected equipment and can prolong any associated outage. Moreover, the connection error can remain unnoticed until an outage occurs, which also increases the time required to pinpoint the root cause of the problem. Aspects of the present disclosure provide a proactive solution for identifying misconnections by evaluating characteristics of Power Line Disturbance (PLD) events.

Aspects of the present disclosure determine if two (or more) incoming electrical utility feeds originate from the same source or if they appear to be separately-sourced power feeds. Aspects of the present disclosure are applicable to single-phase Alternating Current (AC), multi-phase AC, and Direct Current (DC) systems. Each of the utility feeds can be independently characterized. A host microprocessor can then compare the results, identify any differences, and make a determination regarding the independence of the utility feeds. The individual utility feeds can be identified by power line disturbances such as, but are not limited to voltage sags, voltage surges, and/or voltage ringing frequency.

If the microcontroller detects any PLD events, it records the PLD data and reports to a higher-level (host) microcontroller. The host microcontroller can then check and compare for any meaningful similarities between the detected PLD events. The host microcontroller can mark the power devices that experienced similar PLD events, and it can indicate a likelihood that a system is connected to the same energy source.

Aspects of the present disclosure can be incorporated as part of an installed system such that energy feed independence checks can be run on-demand, at periodic intervals, or after maintenance/repair operations at either the system, facility, or utility level. Additionally, aspects of the present disclosure can be powered by the energy feeds under test or from an independent power source (e.g., a battery or unrelated power connection).

As is understood by one skilled in the art, PLD events commonly occur in power distribution systems. PLD events can include voltage surges, voltage sages, temporary overvoltage, and voltage ringing, for example. Magnitudes and durations of various PLD events can vary. Power Distribution Units (PDUs) and/or Power Supply Units (PSUs) are connected to the AC mains and thus can capture the PLD events. For example, data collected from a voltage sag or voltage surge can include a timestamp, a duration, and a magnitude. As another example, data collected from voltage ringing can include a timestamp, a duration, a magnitude, and a ringing frequency. These events can be stored in PLD event logs. A host microcontroller can evaluate the PLD event logs in real-time or in batches covering predetermined periods of time (e.g., days, weeks, months, etc.).

At a high level, aspects of the present disclosure are capable of quantitatively characterizing incoming power feeds to distinguish between facilities and grid dependence of the feeds based on Power Line Disturbance (PLD) events. Thus, aspects of the present disclosure include simultaneously capturing PLD events by time-synchronized microcontrollers. Aspects of the present disclosure are further configured to compare the deviation in magnitude of incoming voltages, the duration of magnitude deviation, and voltage ringing frequencies to user-configurable/defined thresholds. Aspects of the present disclosure are further configured to generate an alert to a higher-level monitoring system if any PDUs and/or PSUs that are supposed to be connected to separate power feeds/phases are marked as connected to the same power feed/phase. Thus, aspects of the present disclosure serve as a mechanism to confirm if the service personnel correctly plugged the input power connections/feeds on the server rack, machine, or system for power redundancy. Advantageously, aspects of the present disclosure avoid unnecessary outages, hazardous conditions and costly replacement of the equipment, and elongated recovery time. One example use case of the present disclosure is predicting imminent failure of power, determining when to switch to a more stable source, and determining when to selectively switch connections of critical components/modules to the more stable power source.

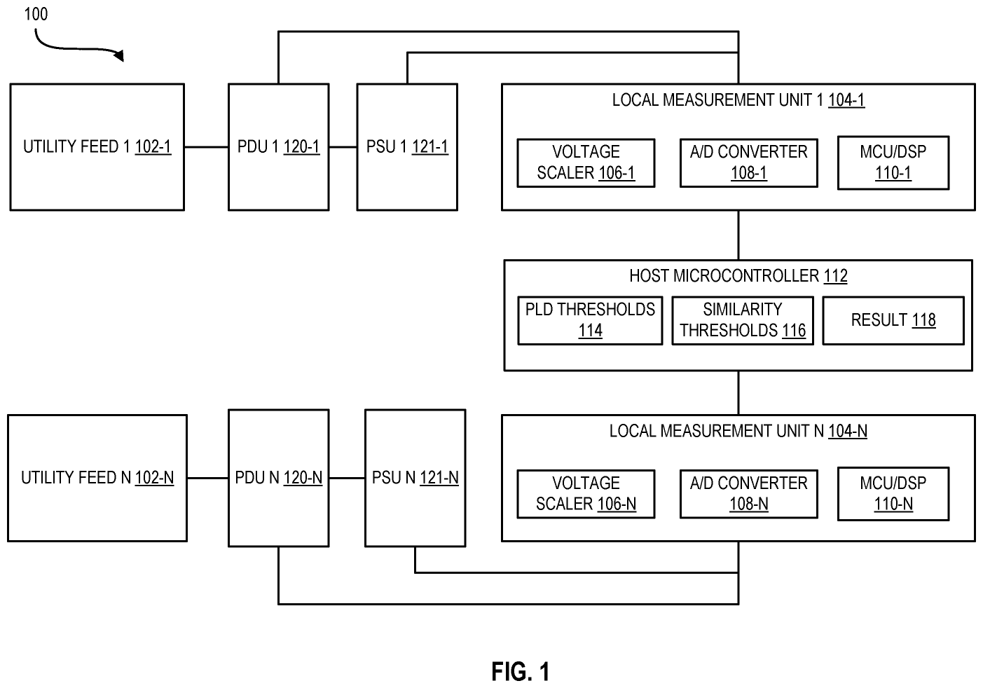

Referring now to the figures, FIG. 1 illustrates a block diagram of an example system 100 for electrical grid origination determination using Power Line Disturbance (PLD) characteristics, in accordance with some embodiments of the present disclosure. The system 100 includes multiple utility feeds 102 (e.g., utility feed 1 102-1, utility feed N 102-N, where N refers to any integer representing several, tens, hundreds, or thousands of utility feeds). Each utility feed 102 can be an AC or DC power source providing power to a Power Distribution Unit (PDU) (e.g., PDU 1 120-1 and PDU N 120-N, collectively referred to as PDU 120), Power Supply Unit (PSU) (e.g., PSU 1 121-1 and PSU N 121-N, collectively referred to as PSU 121), and/or other voltage-powered device. For purposes of the present disclosure, PDUs 120, PSUs 121, and/or other devices connected to the utility feeds 102 can generically be referred to as power units.

The PDUs 120 and/or PSUs 121 are respectively connected to local measurement units 104 (e.g., local measurement unit 1 104-1, local measurement unit N 104-N). More specifically, local measurement units 104 can be incorporated into the PDUs 120, the PSUs 121, or another component communicatively coupled (directly or indirectly) to the PDUs 120 and/or PSUs 121. Additionally, the local measurement units 104 can be incorporated (in whole or in part) into multiple of the aforementioned components (e.g., PDUs 120, PSUs 121, and/or other components). Local measurement units 104 can be any hardware configuration capable of computational processing. Local measurement units 104 can include processing resources, storage resources, networking resources, and other resources configured to enable the local measurement units 104 to perform various functions described in the present disclosure.

The local measurement units 104 can respectively include voltage scalers 106 (e.g., voltage scaler 106-1 and voltage scaler 106-N). Voltage scalers 106 are configured to scale down a high voltage of the utility feed 102 to a smaller voltage that is consumable by an A/D converter 108 (e.g., A/D converter 108-1 and A/D converter 108-N). Voltage scalers 106 can utilize software or hardware mechanisms to scale the voltage from a higher level to a lower level while retaining patterns in the voltage behavior (e.g., surges, sags, ringing, etc.).

A/D converter 108 converts an analog signal to a digital signal. In some aspects of the present disclosure, the A/D converter 108 converts the analog signal of the scaled voltage output by the voltage scaler 106-1 to a digital signal. The digital signal can be processed by a microcontroller unit (MCU) or a digital signal processor (DSP) (e.g., MCU/DSP 110-1 and

MCU/DSP 110-N, collectively referred to as MCU/DSP 110). In some embodiments, the MCU/DSP 110 can monitor the digital signal of the utility feed 102 and record any periods of time including a PLD. In other embodiments, the MCU/DSP 110 formats the digital signal of the utility feed 102 to a format suitable for the host microcontroller 112.

Host microcontroller 112 is communicatively coupled to each local measurement unit 104. In some embodiments, the host microcontroller 112 receives digital signals representing the utility feeds 102 from the local measurement units 104. In other embodiments, the host microcontroller 112 receives snippets of the digital signals representing the utility feed 102, where the snippets represent PLDs detected by the MCU/DSP 110. The PLDs can be characterized using PLD thresholds 114. PLD thresholds can include, for example, a threshold duration, a threshold voltage deviation (e.g., for characterizing voltage sags and voltage surges), and a threshold frequency (e.g., for characterizing voltage ringing).

Host microcontroller 112 can further include similarity thresholds 116 for determining whether two PLDs are similar or not, where similar PLDs can indicate a same utility feed 102 powering multiple devices. The similarity thresholds 116 can include, for example, a timestamp variance threshold (e.g., a time between the onset or conclusion of two PLDs), voltage variance threshold (e.g., a difference between surges or sags between two PLDs), and a frequency variance threshold (e.g., a difference between voltage ringing frequencies between two PLDs).

The host microcontroller 112 can further include results 118. The results 118 can identify which utility feeds 102 power which PDUs 120 and/or PSUs 121. More specifically, the results 118 can indicate if two or more PDUs 120 and/or PSUs 121 are powered by the same utility feed 102 based on similarities in PLDs.

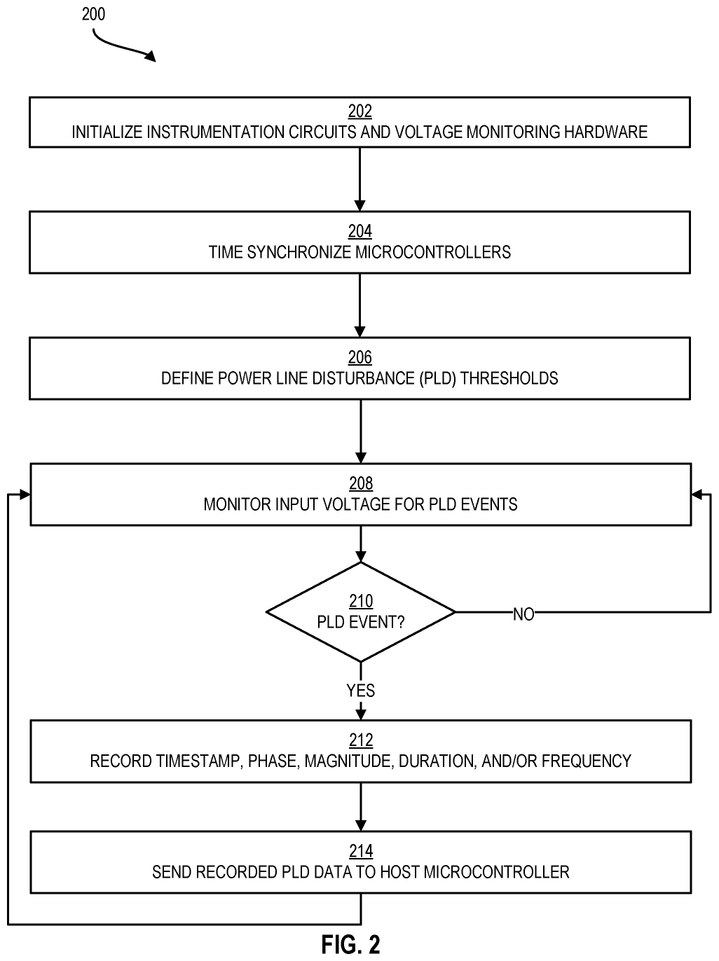

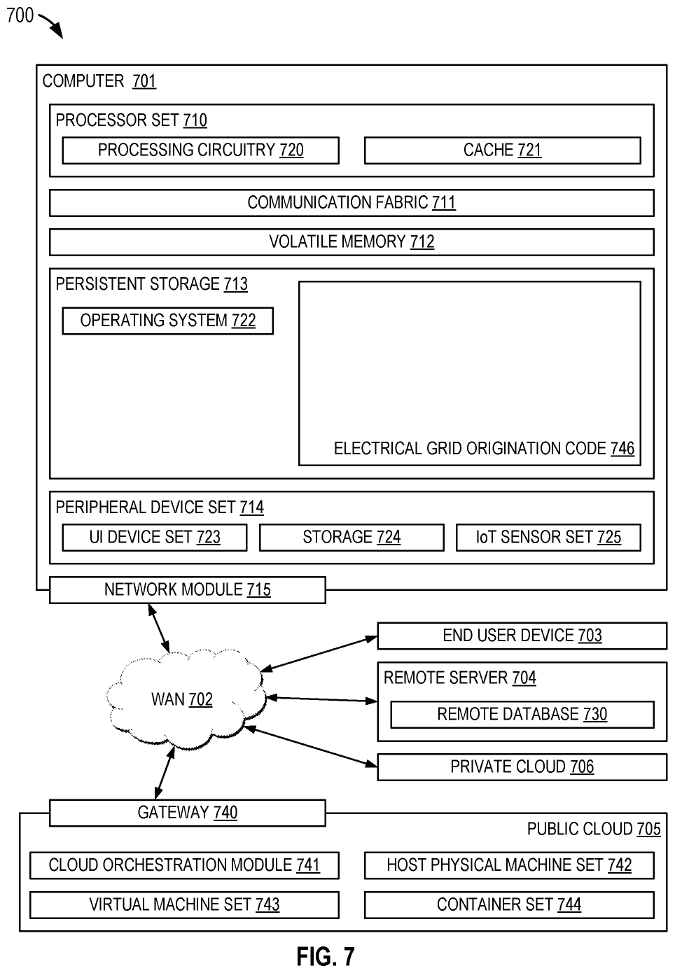

FIG. 2 illustrates a flowchart of an example method 200 for detecting PLD events at a PDU, PSU, and/or other device, in accordance with some embodiments of the present disclosure. In some embodiments, the method 200 is implemented by one or more components of FIG. 1, a microcontroller, a processor, a computer (e.g., computer 701 of FIG. 7), or another configuration of hardware and/or software. In some embodiments, the method 200 is performed by a local measurement unit (e.g., local measurement unit 104 of FIG. 1).

Operation 202 includes initializing instrumentation circuits and voltage monitoring hardware. Operation 202 can include, for example, enabling functionality for the instrumentation circuits and voltage monitoring hardware whether it is incorporated into new electrical equipment, retrofitted onto pre-existing electrical equipment, are connected to a pre-existing electrical equipment as a standalone diagnostic tool. Initialized instrumentation can include, but is not limited to, voltage scalers and A/D converters.

Operation 204 includes time synchronizing microcontrollers coupled to the various PDUs/PSUs. Time synchronizing the microcontrollers enables a determination of whether different microcontrollers connected to different PDUs/PSUs detected a same PLD, indicating the different PDUs/PSUs are connected to a same electrical feed.

Operation 206 includes defining PLD thresholds. PLD thresholds can be based on duration characteristics, magnitude of deviation characteristics, and/or frequency characteristics, among other possible characteristics. In some embodiments, the PLD thresholds are customizable based on phase information of the monitored input voltages.

Operation 208 includes monitoring input voltages for PLD events. Operation 208 can be real-time monitoring or monitoring that is performed post-collection as part of a batch processing protocol. Operation 208 can include performing voltage measurements based on Root Mean Square (RMS), average, peak-to-peak, and/or other voltage measurement strategies.

Operation 210 includes determining if a PLD event has occurred. For example, operation 210 can compare the monitored input voltages to the PLD thresholds. If the monitored input voltages do not satisfy the PLD thresholds (210: NO), then the method 200 returns to operation 208 and continues monitoring the input voltage for PLD events. If the monitored input voltage satisfies one or more PLD thresholds (210: YES), then the method 200 proceeds to operation 212.

Operation 212 includes recording timestamp, phase, magnitude, duration, and/or frequency associated with the identified PLD event. Operation 214 includes sending recorded PLD data to a host microcontroller. Operation 214 can provide the information needed for the host microcontroller to characterize whether different PDUs/PSUs are receiving power from a same or different electrical source based on similarities or differences between detected PLDs. Following operation 214, the method 200 returns to operation 208 to continue monitoring for additional PLD events.

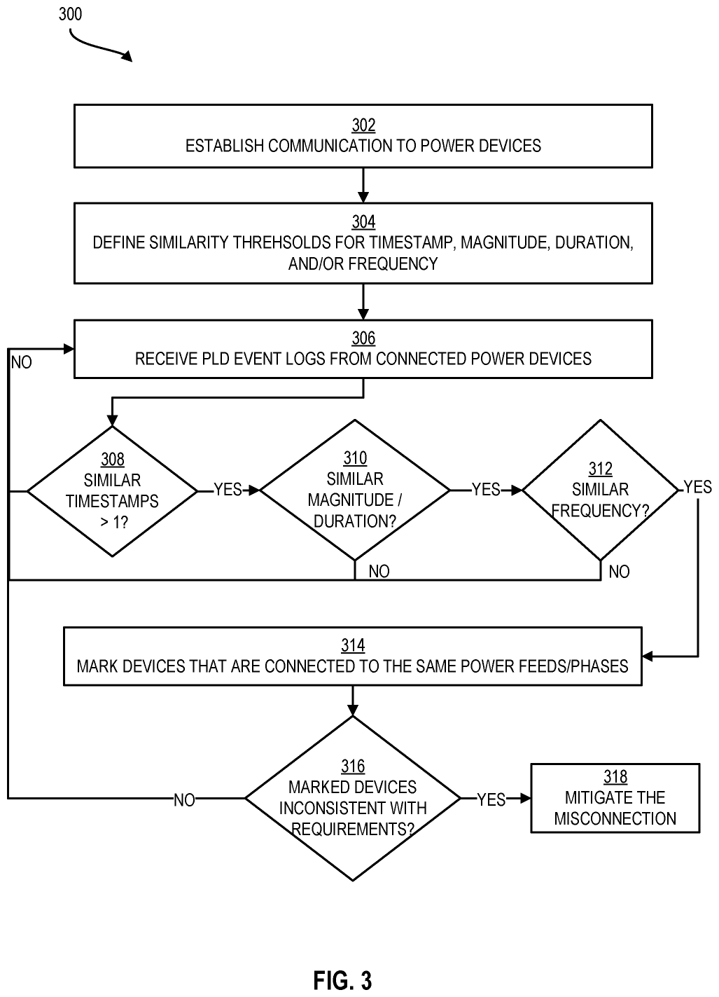

FIG. 3 illustrates a flowchart of an example method for determining whether detected PLD events indicate two or more devices (e.g., PDUs, PSUs, and/or other devices) are improperly connected to a same power source, in accordance with some embodiments of the present disclosure. In some embodiments, the method 300 is implemented by one or more components of FIG. 1, a microcontroller, a processor, a computer (e.g., computer 701 of FIG. 7), or another configuration of hardware and/or software. In some embodiments, the method 300 is implemented by a host microcontroller (e.g., host microcontroller 112 of FIG. 1). In some embodiments, the method 300 is performed after the method 200.

Operation 302 includes establishing communication to power devices (e.g., PDUs and/or PSUs). In some embodiments, operation 302 establishes connections between local measurement units and a host microcontroller.

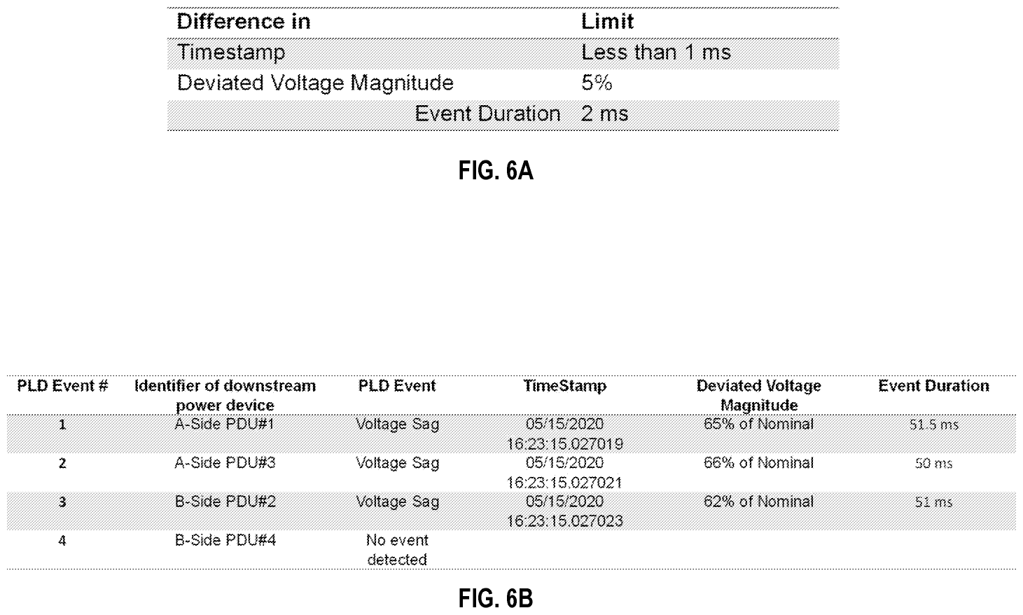

Operation 304 includes defining similarity thresholds for timestamp, magnitude, duration, and/or frequency characteristics. Example similarity thresholds are discussed in more detail hereinafter with respect to FIG. 6A.

Operation 306 includes receiving a PLD event log from the connected power devices. In some embodiments, the PLD event log is received at a host microcontroller and from one or multiple local measurement units.

Operation 308 includes determining if two or more PLD events have similar timestamps according to the timestamp similarity threshold defined in operation 304. If not (308: NO), then the method 300 returns to operation 306 and awaits additional PLD event logs. If so (308: YES), then the method 300 proceeds to operation 310.

Operation 310 includes determining if the PLD event logs with similar timestamps have similar magnitude and/or duration characteristics based on the magnitude and/or duration similarity thresholds defined in operation 304. If not (310: NO), then the method 300 returns to operation 306 and awaits additional PLD event logs. If so (310: YES), then the method 300 proceeds to operation 312.

Operation 312 includes determining if the PLD event logs with similar timestamps and similar magnitudes and/or durations also share a similar frequency according to a frequency similarity threshold defined in operation 304. If not (312: NO), then the method 300 returns to operation 306 and awaits additional PLD event logs. If so (312: YES), then the method 300 proceeds to operation 314.

As will be appreciated by one skilled in the art, a variety of decision blocks that are similar or dissimilar in nature to operations 308, 310, and 312 can be utilized to determine whether different devices are connected to the same power feed. As one example, different control paths can be created based on a type of PLD event (e.g., voltage surge, voltage sag, voltage ringing) such that some determinations are made for voltage sags/surges while other determinations are made for voltage ringing.

Operation 314 includes marking devices associated with PLD events that have similar timestamps, similar magnitudes and/or durations, and similar frequencies as being connected to the same power feeds and/or phases.

Operation 316 includes determining if the devices marked in operation 314 as being connected to the same power feeds and/or phases are inconsistent with design requirements for the marked devices. In other words, operation 316 determines whether the marked devices (determined to be receiving power from the same power source) should, in fact, be connected to different power sources. If the marked devices connected to the same power source are not inconsistent with the design requirements (316: NO), then the method 300 returns to operation 306 and awaits additional PLD event logs. If the marked devices connected to the same power source are inconsistent with the design requirements (316: YES), then the method 300 proceeds to operation 318.

Operation 318 includes mitigating the misconnection. Operation 318 can include, for example, transmitting an alert to a user interface indicating that two or more power devices are incorrectly connected to a same power source together with identifying information regarding the two or more power devices and the same power source. In some embodiments, operation 318 includes automatically managing the two or more power devices until a correction can be made, where the automatic management can throttle power to the two or more power devices to reduce a risk of overloading the same power supply.

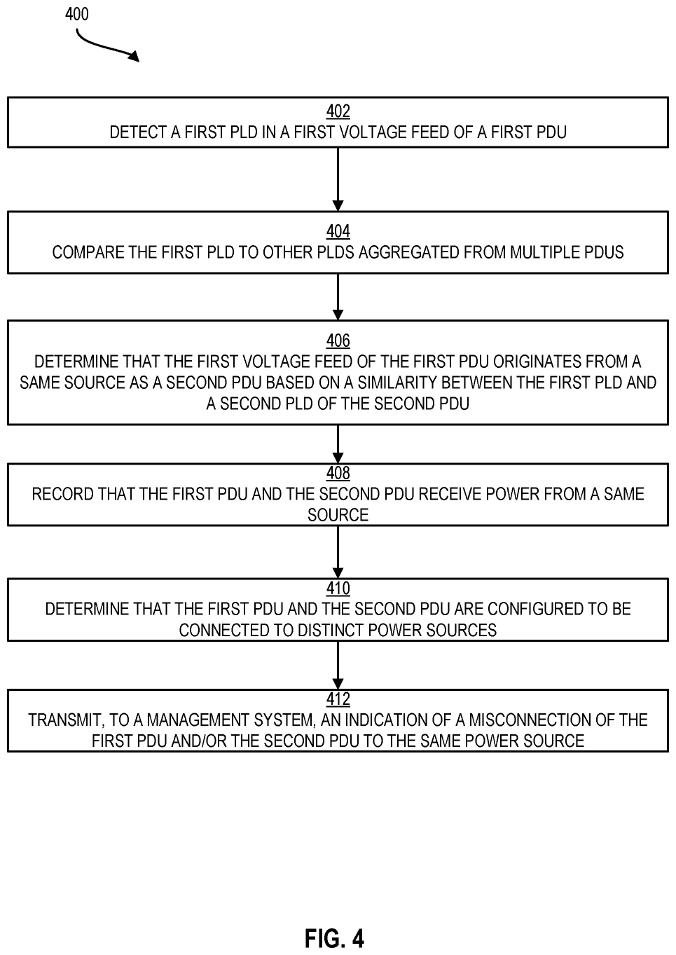

FIG. 4 illustrates a flowchart of an example method 400 for detecting a misconnection of multiple PDUs to a same power source based on PLD events, in accordance with some embodiments of the present disclosure. In some embodiments, the method 400 is implemented by one or more components of FIG. 1, a microcontroller, a processor, a computer (e.g., computer 701 of FIG. 7), or another configuration of hardware and/or software.

Operation 402 includes detecting a first PLD in a first voltage feed of a first PDU. Although a PDU is discussed in operation 402, FIG. 4 can likewise be implemented with a PSU or any other device communicatively coupled to the first voltage feed. Operation 404 includes comparing the first PLD to other PLDs aggregated from multiple PDUs. Operation 406 includes determining that the first voltage feed of the first PDU originates from a same source as a second PDU based on a similarity between the first PLD and a second PLD of the second PDU. Operation 408 includes recording that the first PDU and the second PDU receive power from a same source. Operation 410 includes determining that the first PDU and the second PDU are configured to be connected to distinct power sources. Operation 412 includes transmitting, to a management system, an indication of a misconnection of the first PDU and/or the second PDU to the same power source.

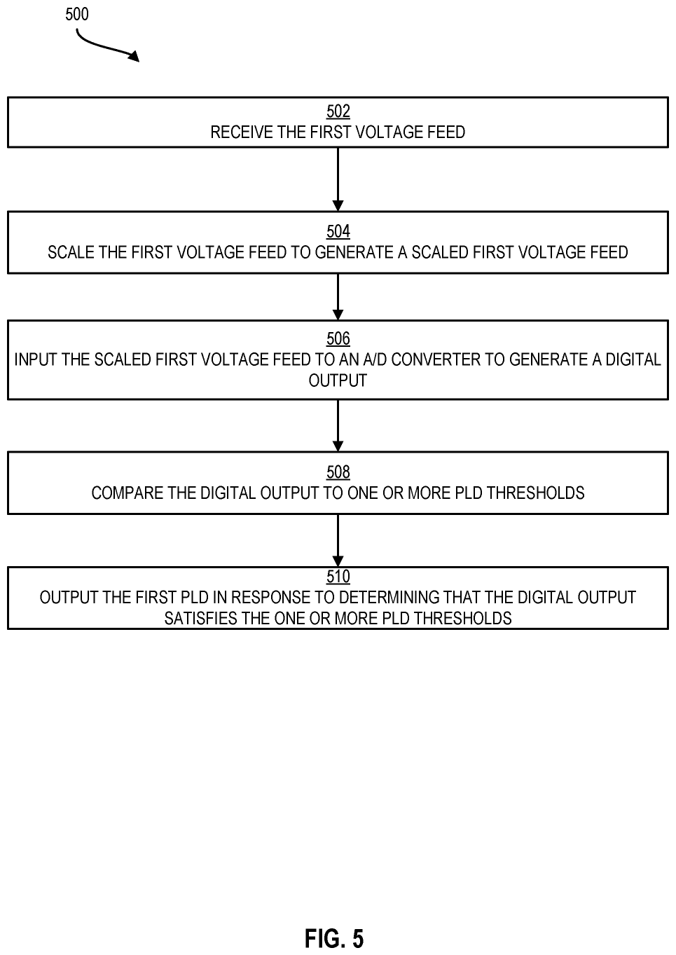

FIG. 5 illustrates a flowchart of an example method 500 for detecting a PLD event, in accordance with some embodiments of the present disclosure. In some embodiments, the method 500 is implemented by one or more components of FIG. 1, a microcontroller, a processor, a computer (e.g., computer 701 of FIG. 7), or another configuration of hardware and/or software. In some embodiments, the method 500 is a sub-method of operation 402 of the method 400 of FIG. 4.

Operation 502 includes receiving the first voltage feed. Operation 504 includes scaling the first voltage feed to generate a scaled first voltage feed. Operation 504 can utilize a voltage scaler to scale the first voltage feed. Operation 506 includes inputting the scaled first voltage feed to an A/D converter to generate a digital output. Operation 508 includes comparing the digital output to one or more PLD thresholds. Operation 510 includes outputting the first PLD in response to determining that the digital output satisfies the one or more PLD thresholds.

FIG. 6A illustrates an example table including example similarity thresholds for identifying multiple PLD events as being a same PLD event such as timestamp variation, voltage magnitude deviation, and event duration, in accordance with some embodiments of the present disclosure. As shown in FIG. 6A, various thresholds can be defined such as a timestamp threshold (e.g., a difference between PLD events of less than 1 millisecond), a deviated voltage magnitude threshold (e.g., a difference between deviated voltage magnitudes of PLD events of less than 5%), and an event duration threshold (e.g., a difference between durations of PLD events of less than 2 milliseconds). Although not explicitly shown, the table shown in FIG. 6A can also include a deviation in voltage ringing frequency for PLD events characterized as voltage ringing.

FIG. 6B illustrates an example table including example PLDs and their utility in characterizing electrical grid origination for various PDUs, in accordance with some embodiments of the present disclosure. FIG. 6B illustrates four example PLD events. For each PLD event, FIG. 6B includes an identifier of the downstream power device (e.g., PDU or PSU), a type of PLD event, a timestamp, a deviated voltage magnitude, and an event duration.

Evaluating the contents of FIG. 6B using the thresholds established in FIG. 6A, it can be seen that PLD events 1, 2, and 3 utilize the same power source. For example, PLD events 1, 2, and 3 have timestamps that are less than 1 millisecond apart, differences in deviated voltage magnitudes of less than 5%, and differences in event durations of less than 2 milliseconds.

Thus, aspects of the present disclosure can determine that PLD events 1, 2, and 3 are a same PLD event and thus, the associated PDUs/PSUs are connected to a same power source. Additionally, aspects of the present disclosure can evaluate the identifier of the downstream power device to determine whether the same or different power sources should be powering the associated devices. As shown in FIG. 6B, PLD events 1 and 2 both utilize A-Side power feed whereas PLD event 3 utilizes B-Side power feed. Thus, aspects of the present disclosure can determine that B-Side PDU #2 is incorrectly connected to the A-Side power feed based on a comparison of the PLD events. In this way, aspects of the present disclosure can identify and correct misconnections. In doing so, aspects of the present disclosure can reduce power outages and/or equipment damage resulting from misconnected PDUs.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

FIG. 7 illustrates a block diagram of an example computing environment, in accordance with some embodiments of the present disclosure. Computing environment 700 contains an example of an environment for the execution of at least some of the computer code involved in performing the inventive methods, such as electrical grid origination code 746. In addition to electrical grid origination code 746, computing environment 700 includes, for example, computer 701, wide area network (WAN) 702, end user device (EUD) 703, remote server 704, public cloud 705, and private cloud 706. In this embodiment, computer 701 includes processor set 710 (including processing circuitry 720 and cache 721), communication fabric 711, volatile memory 712, persistent storage 713 (including operating system 722 and electrical grid origination code 746, as identified above), peripheral device set 714 (including user interface (UI), device set 723, storage 724, and Internet of Things (IoT) sensor set 725), and network module 715. Remote server 704 includes remote database 730. Public cloud 705 includes gateway 740, cloud orchestration module 741, host physical machine set 742, virtual machine set 743, and container set 744.

COMPUTER 701 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 730. As is well understood in the art of computer technology, and depending upon the technology, performance of a computer-implemented method may be distributed among multiple computers and/or between multiple locations. On the other hand, in this presentation of computing environment 700, detailed discussion is focused on a single computer, specifically computer 701, to keep the presentation as simple as possible. Computer 701 may be located in a cloud, even though it is not shown in a cloud in FIG. 7. On the other hand, computer 701 is not required to be in a cloud except to any extent as may be affirmatively indicated.

PROCESSOR SET 710 includes one, or more, computer processors of any type now known or to be developed in the future. Processing circuitry 720 may be distributed over multiple packages, for example, multiple, coordinated integrated circuit chips. Processing circuitry 720 may implement multiple processor threads and/or multiple processor cores. Cache 721 is memory that is located in the processor chip package(s) and is typically used for data or code that should be available for rapid access by the threads or cores running on processor set 710. Cache memories are typically organized into multiple levels depending upon relative proximity to the processing circuitry. Alternatively, some, or all, of the cache for the processor set may be located “off chip.” In some computing environments, processor set 710 may be designed for working with qubits and performing quantum computing.

Computer readable program instructions are typically loaded onto computer 701 to cause a series of operational steps to be performed by processor set 710 of computer 701 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 721 and the other storage media discussed below. The program instructions, and associated data, are accessed by processor set 710 to control and direct performance of the inventive methods. In computing environment 700, at least some of the instructions for performing the inventive methods may be stored in electrical grid origination code 746 in persistent storage 713.

COMMUNICATION FABRIC 711 is the signal conduction paths that allow the various components of computer 701 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 712 is any type of volatile memory now known or to be developed in the future. Examples include dynamic type random access memory (RAM) or static type RAM. Typically, the volatile memory is characterized by random access, but this is not required unless affirmatively indicated. In computer 701, the volatile memory 712 is located in a single package and is internal to computer 701, but, alternatively or additionally, the volatile memory may be distributed over multiple packages and/or located externally with respect to computer 701.

PERSISTENT STORAGE 713 is any form of non-volatile storage for computers that is now known or to be developed in the future. The non-volatility of this storage means that the stored data is maintained regardless of whether power is being supplied to computer 701 and/or directly to persistent storage 713. Persistent storage 713 may be a read only memory (ROM), but typically at least a portion of the persistent storage allows writing of data, deletion of data and re-writing of data. Some familiar forms of persistent storage include magnetic disks and solid state storage devices. Operating system 722 may take several forms, such as various known proprietary operating systems or open source Portable Operating System Interface type operating systems that employ a kernel. The code included in electrical grid origination code 746 typically includes at least some of the computer code involved in performing the inventive methods.

PERIPHERAL DEVICE SET 714 includes the set of peripheral devices of computer 701. Data communication connections between the peripheral devices and the other components of computer 701 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 723 may include components such as a display screen, speaker, microphone, wearable devices (such as goggles and smart watches), keyboard, mouse, printer, touchpad, game controllers, and haptic devices. Storage 724 is external storage, such as an external hard drive, or insertable storage, such as an SD card. Storage 724 may be persistent and/or volatile. In some embodiments, storage 724 may take the form of a quantum computing storage device for storing data in the form of qubits. In embodiments where computer 701 is required to have a large amount of storage (for example, where computer 701 locally stores and manages a large database) then this storage may be provided by peripheral storage devices designed for storing very large amounts of data, such as a storage area network (SAN) that is shared by multiple, geographically distributed computers. IoT sensor set 725 is made up of sensors that can be used in Internet of Things applications. For example, one sensor may be a thermometer and another sensor may be a motion detector.

NETWORK MODULE 715 is the collection of computer software, hardware, and firmware that allows computer 701 to communicate with other computers through WAN 702. Network module 715 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 715 are performed on the same physical hardware device. In other embodiments (for example, embodiments that utilize software-defined networking (SDN)), the control functions and the forwarding functions of network module 715 are performed on physically separate devices, such that the control functions manage several different network hardware devices. Computer readable program instructions for performing the inventive methods can typically be downloaded to computer 701 from an external computer or external storage device through a network adapter card or network interface included in network module 715.

WAN 702 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 703 is any computer system that is used and controlled by an end user (for example, a customer of an enterprise that operates computer 701), and may take any of the forms discussed above in connection with computer 701. EUD 703 typically receives helpful and useful data from the operations of computer 701. For example, in a hypothetical case where computer 701 is designed to provide a recommendation to an end user, this recommendation would typically be communicated from network module 715 of computer 701 through WAN 702 to EUD 703. In this way, EUD 703 can display, or otherwise present, the recommendation to an end user. In some embodiments, EUD 703 may be a client device, such as thin client, heavy client, mainframe computer, desktop computer and so on.

REMOTE SERVER 704 is any computer system that serves at least some data and/or functionality to computer 701. Remote server 704 may be controlled and used by the same entity that operates computer 701. Remote server 704 represents the machine(s) that collect and store helpful and useful data for use by other computers, such as computer 701. For example, in a hypothetical case where computer 701 is designed and programmed to provide a recommendation based on historical data, then this historical data may be provided to computer 701 from remote database 730 of remote server 704.

PUBLIC CLOUD 705 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 705 is performed by the computer hardware and/or software of cloud orchestration module 741. The computing resources provided by public cloud 705 are typically implemented by virtual computing environments that run on various computers making up the computers of host physical machine set 742, which is the universe of physical computers in and/or available to public cloud 705. The virtual computing environments (VCEs) typically take the form of virtual machines from virtual machine set 743 and/or containers from container set 744. It is understood that these VCEs may be stored as images and may be transferred among and between the various physical machine hosts, either as images or after instantiation of the VCE. Cloud orchestration module 741 manages the transfer and storage of images, deploys new instantiations of VCEs and manages active instantiations of VCE deployments. Gateway 740 is the collection of computer software, hardware, and firmware that allows public cloud 705 to communicate through WAN 702.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 706 is similar to public cloud 705, except that the computing resources are only available for use by a single enterprise. While private cloud 706 is depicted as being in communication with WAN 702, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 705 and private cloud 706 are both part of a larger hybrid cloud.

The flowchart and block diagrams in the Figures illustrate the architecture, functionality, and operation of possible implementations of systems, methods, and computer program products according to various embodiments of the present invention. In this regard, each block in the flowchart or block diagrams can represent a module, segment, or subset of instructions, which comprises one or more executable instructions for implementing the specified logical function(s). In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While it is understood that the process software (e.g., any software configured to perform any portion of the methods described previously and/or implement any of the functionalities described previously) can be deployed by manually loading it directly in the client, server, and proxy computers via loading a storage medium such as a CD, DVD, etc., the process software can also be automatically or semi-automatically deployed into a computer system by sending the process software to a central server or a group of central servers. The process software is then downloaded into the client computers that will execute the process software. Alternatively, the process software is sent directly to the client system via e-mail. The process software is then either detached to a directory or loaded into a directory by executing a set of program instructions that detaches the process software into a directory. Another alternative is to send the process software directly to a directory on the client computer hard drive. When there are proxy servers, the process will select the proxy server code, determine on which computers to place the proxy servers' code, transmit the proxy server code, and then install the proxy server code on the proxy computer. The process software will be transmitted to the proxy server, and then it will be stored on the proxy server.

Embodiments of the present invention can also be delivered as part of a service engagement with a client corporation, nonprofit organization, government entity, internal organizational structure, or the like. These embodiments can include configuring a computer system to perform, and deploying software, hardware, and web services that implement, some or all of the methods described herein. These embodiments can also include analyzing the client's operations, creating recommendations responsive to the analysis, building systems that implement subsets of the recommendations, integrating the systems into existing processes and infrastructure, metering use of the systems, allocating expenses to users of the systems, and billing, invoicing (e.g., generating an invoice), or otherwise receiving payment for use of the systems.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments can be practiced. These embodiments were described in sufficient detail to enable those skilled in the art to practice the embodiments, but other embodiments can be used and logical, mechanical, electrical, and other changes can be made without departing from the scope of the various embodiments. In the previous description, numerous specific details were set forth to provide a thorough understanding the various embodiments. But the various embodiments can be practiced without these specific details. In other instances, well-known circuits, structures, and techniques have not been shown in detail in order not to obscure embodiments.

Different instances of the word “embodiment” as used within this specification do not necessarily refer to the same embodiment, but they can. Any data and data structures illustrated or described herein are examples only, and in other embodiments, different amounts of data, types of data, fields, numbers and types of fields, field names, numbers and types of rows, records, entries, or organizations of data can be used. In addition, any data can be combined with logic, so that a separate data structure may not be necessary. The previous detailed description is, therefore, not to be taken in a limiting sense.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present disclosure has been described in terms of specific embodiments, it is anticipated that alterations and modification thereof will become apparent to the skilled in the art. Therefore, it is intended that the following claims be interpreted as covering all such alterations and modifications as fall within the true spirit and scope of the disclosure.

Any advantages discussed in the present disclosure are example advantages, and embodiments of the present disclosure can exist that realize all, some, or none of any of the discussed advantages while remaining within the spirit and scope of the present disclosure.

The following example clauses illustrate a non-limiting listing of aspects of the present disclosure.

Clause 1. A computer-implemented method comprising: detecting a first Power Line Disturbance (PLD) in a first voltage feed of a first power unit at a first time; comparing the first PLD to other PLDs aggregated from multiple power units; determining that the first voltage feed of the first power unit originates from a same source as a second power unit based on a similarity between the first PLD and a second PLD of the second power unit satisfying a similarity threshold and occurring within a same timeframe proximate to the first time; and recording that the first power unit and the second power unit receive power from the same source.

Clause 2. The computer-implemented method of clause 1, further comprising: determining that the first power unit and the second power unit are configured to be connected to distinct power sources; and transmitting, to a management system, an indication of a misconnection of the first power unit and/or the second power unit to the same source.

Clause 3. The computer-implemented method of clause 1, wherein the first PLD is based on a voltage surge.

Clause 4. The computer-implemented method of clause 1, wherein the first PLD is based on a voltage sag.

Clause 5. The computer-implemented method of clause 1, wherein the first PLD is based on voltage ringing.

Clause 6. The computer-implemented method of clause 1, wherein detecting the first PLD further comprises: receiving the first voltage feed; scaling the first voltage feed to generate a scaled first voltage feed; inputting the scaled first voltage feed to an Analog-to-Digital converter to generate a digital output; comparing the digital output to a PLD threshold; and outputting the first PLD in response to determining that the digital output satisfies the PLD threshold.

Clause 7. The computer-implemented method of clause 1, wherein the first PLD includes a timestamp, phase information, a magnitude of a voltage disturbance, a duration of the voltage disturbance, and a ringing frequency of the voltage disturbance.

Clause 8. The computer-implemented method of clause 1, wherein the first PLD has a duration within an inclusive range of 1 millisecond (ms) to 10 seconds(s).

Clause 9. The computer-implemented method of clause 1, wherein the computer-implemented method is executed by a computational device based on electrical grid origination code downloaded to the computational device from a remote data processing system; and wherein the computer-implemented method further comprises: metering usage of the electrical grid origination code; and generating an invoice based on metering the usage of the electrical grid origination code.

Clause 10. The computer-implemented method of clause 1, wherein the first power unit and the second power unit are selected from a group consisting of: Power Distribution Units (PDUs), and Power Supply Units (PSUs).

Clause 11. A system comprising: one or more processors; and one or more computer-readable storage media storing program instructions which, when executed by the one or more processors, are configured to cause the one or more processors to perform a method according to any one of clauses 1 to 10.

Clause 12. A computer program product comprising one or more computer readable storage media, and program instructions collectively stored on the one or more computer readable storage media, the program instructions comprising instructions configured to cause one or more processors to perform a method according to any one of clauses 1 to 10.

What is claimed is:

1. A computer-implemented method comprising:
detecting a first Power Line Disturbance (PLD) in a first voltage feed of a first power unit at a first time;
comparing the first PLD to other PLDs aggregated from multiple power units;
determining that the first voltage feed of the first power unit originates from a same source as a second power unit based on a similarity between the first PLD and a second PLD of the second power unit satisfying a similarity threshold and occurring within a same timeframe proximate to the first time; and
recording that the first power unit and the second power unit receive power from the same source.

2. The computer-implemented method of claim 1, further comprising:
determining that the first power unit and the second power unit are configured to be connected to distinct power sources; and
transmitting, to a management system, an indication of a misconnection of the first power unit and/or the second power unit to the same source.

3. The computer-implemented method of claim 1, wherein the first PLD is based on a voltage surge.

4. The computer-implemented method of claim 1, wherein the first PLD is based on a voltage sag.

5. The computer-implemented method of claim 1, wherein the first PLD is based on voltage ringing.

6. The computer-implemented method of claim 1, wherein detecting the first PLD further comprises:
receiving the first voltage feed;
scaling the first voltage feed to generate a scaled first voltage feed;
inputting the scaled first voltage feed to an Analog-to-Digital converter to generate a digital output;
comparing the digital output to a PLD threshold; and
outputting the first PLD in response to determining that the digital output satisfies the PLD threshold.

7. The computer-implemented method of claim 1, wherein the first PLD includes a timestamp, phase information, a magnitude of a voltage disturbance, a duration of the voltage disturbance, and a ringing frequency of the voltage disturbance.

8. The computer-implemented method of claim 1, wherein the first PLD has a duration within an inclusive range of 1 millisecond (ms) to 10 seconds(s).

9. The computer-implemented method of claim 1, wherein the computer-implemented method is executed by a computational device based on electrical grid origination code downloaded to the computational device from a remote data processing system.

10. The computer-implemented method of claim 1, wherein the first power unit and the second power unit are selected from a group consisting of: Power Distribution Units (PDUs), and Power Supply Units (PSUs).

11. A system comprising:
one or more processors; and
one or more computer-readable storage media storing program instructions which, when executed by the one or more processors, are configured to cause the one or more processors to perform a method comprising:
detecting a first Power Line Disturbance (PLD) in a first voltage feed of a first power unit at a first time;
comparing the first PLD to other PLDs aggregated from multiple power units;
determining that the first voltage feed of the first power unit originates from a same source as a second power unit based on a similarity between the first PLD and a second PLD of the second power unit satisfying a similarity threshold and occurring within a same timeframe proximate to the first time; and
recording that the first power unit and the second power unit receive power from the same source.

12. The system of claim 11, wherein the one or more computer readable storage media further comprise additional program instructions, which, when executed by the one or more processors, are configured to cause the one or more processors to perform the method further comprising:
determining that the first power unit and the second power unit are configured to be connected to distinct power sources; and
transmitting, to a management system, an indication of a misconnection of the first power unit and/or the second power unit to the same source.

13. The system of claim 11, wherein the first PLD is based on one or more selected from a group consisting of: a voltage surge, a voltage sag, and voltage ringing.

14. The system of claim 11, wherein the one or more computer readable storage media further comprise additional program instructions, which, when executed by the one or more processors, are configured to cause the one or more processors to detect the first PLD further by:
receiving the first voltage feed;
scaling the first voltage feed to generate a scaled first voltage feed;
inputting the scaled first voltage feed to an Analog-to-Digital converter to generate a digital output;
comparing the digital output to a PLD threshold; and
outputting the first PLD in response to determining that the digital output satisfies the PLD threshold.

15. The system of claim 11, wherein the first PLD includes a timestamp, phase information, a magnitude of a voltage disturbance, a duration of the voltage disturbance, and a ringing frequency of the voltage disturbance.

16. A computer program product comprising one or more computer readable storage media, and program instructions collectively stored on the one or more computer readable storage media, the program instructions comprising instructions configured to cause one or more processors to perform a method comprising:
detecting a first Power Line Disturbance (PLD) in a first voltage feed of a first power unit at a first time;
comparing the first PLD to other PLDs aggregated from multiple power units;
determining that the first voltage feed of the first power unit originates from a same source as a second power unit based on a similarity between the first PLD and a second PLD of the second power unit satisfying a similarity threshold and occurring within a same timeframe proximate to the first time; and
recording that the first power unit and the second power unit receive power from the same source.

17. The computer program product of claim 16, wherein the one or more computer readable storage media further comprise additional program instructions, which, when executed by the one or more processors, are configured to cause the one or more processors to perform the method further comprising:
determining that the first power unit and the second power unit are configured to be connected to distinct power sources; and
transmitting, to a management system, an indication of a misconnection of the first power unit and/or the second power unit to the same source.

18. The computer program product of claim 16, wherein the first PLD is based on one or more selected from a group consisting of: a voltage surge, a voltage sag, and voltage ringing.

19. The computer program product of claim 16, wherein the one or more computer readable storage media further comprise additional program instructions, which, when executed by the one or more processors, are configured to cause the one or more processors to detect the first PLD further by:
receiving the first voltage feed;
scaling the first voltage feed to generate a scaled first voltage feed;
inputting the scaled first voltage feed to an Analog-to-Digital converter to generate a digital output;
comparing the digital output to a PLD threshold; and
outputting the first PLD in response to determining that the digital output satisfies the PLD threshold.

20. The computer program product of claim 16, wherein the first PLD includes a timestamp, phase information, a magnitude of a voltage disturbance, a duration of the voltage disturbance, and a ringing frequency of the voltage disturbance.
